(19) United States
(12) Patent Application Publication
(10) Pub. No.: US 2008/0283277 A1
(43) Pub. Date: Nov. 20, 2008

(54) WIRING BOARD MANUFACTURING METHOD AND WIRING BOARD

(75) Inventors: Shigetsugu MURAMATSU, Nagano-shi (JP); Yasuhiko KUSAMA, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/113,568

(22) Filed: May 1, 2008

(30) Foreign Application Priority Data
May 14, 2007 (JP) 2007-128470

(51) Int. Cl. H05K 3/00; H05K 1/00

(52) U.S. Cl. 174/250; 29/846

(57) ABSTRACT

A wiring board 100 has a multilayer structure in which insulating layers and wiring layers are arranged on upper and lower surfaces of a core substrate 240, and has a via structure 200 in which electrolytic Cu plating is carried out over a via forming opening provided by patterning a resist layer to form a via 220. A through hole 244 and a wiring pattern 210 to be connected to the through hole 244 are formed on the core substrate 240. The via 220 taking a cylindrical shape is mounted on an upper surface of the wiring pattern 210 and a wiring pattern 230 is formed on an upper surface of the via 220. The via structure 200 is constituted by the wiring pattern 210, the via 220 and the wiring pattern 230, and the through hole 244, the wiring pattern 210, the via 220 and the wiring pattern 230 are electrically connected respectively.

### BACKGROUND OF THE INVENTION

The present invention relates to a method of manufacturing a wiring board and the wiring board, and more particularly to a method of manufacturing a wiring board in which a via is provided to electrically connect wiring patterns formed between insulating layers of a multilayer substrate and the wiring board.

For example, in a wiring board having a multilayer substrate structure, there has widely been used a configuration in which a plurality of wiring patterns formed between insulating layers is electrically connected to each other through a via. As a method of forming the via, for example, there has been used a method of irradiating a laser beam from a laser processing machine on a resin layer constituted by a thermosetting epoxy resin to form a via hole, for example (see Patent Document 1, for instance).

If a position on which the laser beam is irradiated has a variation, moreover, there is a possibility that the laser beam might be irradiated on a position shifted from a position in which the via is formed. For this reason, a receiving pad serving as a stopper for the laser beam is formed on a lower layer wiring pattern in the position in which the via is formed. The receiving pad is formed to have a larger diameter than a via diameter. Even if the position on which the laser beam is irradiated is shifted from the position of the via, therefore, the laser beam can be prevented from getting off from the receiving pad (see Patent Document 2, for example).

FIG. 1A is a perspective view showing an example of structures of a via and a wiring pattern according to the conventional art. FIG. 1B is a plan view showing the example of the structures of the via and the wiring pattern. As shown in FIG. 1A, a lower wiring pattern 10 formed on a lower part of an insulating layer (which is not shown in FIG. 1A) and an upper wiring pattern 20 formed on an upper part of the insulating layer are electrically connected to each other through a via 30 penetrating through the insulating layer. The via 30 is formed by irradiating a laser beam from a laser processing machine on a resin layer constituted by an epoxy resin to form a via hole and depositing a conductive metal in the via hole through a plating method.

As shown in FIG. 1B, in the case in which the via 30 having a diameter of Dv≈60 μm is formed, for example, receiving pads 40 and 50 having larger diameters than the via 30 are provided on upper and lower parts of the via 30 in consideration of a positional shift (an error) in the irradiation of the laser beam. Each of the receiving pads 40 and 50 is formed in a size having a diameter of approximately Dp≈100 μm which is a little less than a double of the diameter Dv of the via 30, for example. Moreover, a wiring width W of wiring patterns 42 and 52 connected to the receiving pads 40 and 50 is usually smaller than the diameter Dv of the via 30 (W<Dv).

A method of manufacturing the conventional wiring board will be described with reference to respective steps in FIGS. 2A to 2I. In FIG. 2A, a through hole 62 is formed on a core substrate 60 and a plated through hole 64 is formed on the through hole 62, and furthermore, the receiving pad 40 to be connected to the through hole 62 is formed on upper and lower surfaces of the core substrate 60. Similarly, insulating layers and wiring patterns are arranged on the upper and lower surfaces of the core substrate 60.

In FIG. 2B, a resin layer constituted by a thermosetting epoxy resin is arranged on the upper and lower surfaces of the core substrate 60 to form a first insulating layer 70. The first insulating layer 70 is formed by laminating a resin film or applying a liquid resin.

In FIG. 2C, a laser beam generated by the laser processing machine is irradiated on the first insulating layer 70 to form a via hole 72. A position on which the laser beam is irradiated is adjusted to be coincident with a center of the receiving pad 40 of the wiring pattern. The receiving pad 40 is provided as a stopper for the laser beam, and is formed to have a larger diameter than the laser beam so as not to cause the laser beam to get off even if the position on which the laser is irradiated is shifted.

The diameter Dv of the via hole 72 processed by the laser beam is smaller than the diameter Dp of the receiving pad 40 (Dv<Dp). Even if a variation (an error) is made within a range of Dv−Dp, therefore, the via hole 72 can be processed in such a manner that a part of the receiving pad 40 is exposed to a bottom part of the via hole 72. The variation (error) includes a variation in the positions of the receiving pad 40 and the laser beam and a variation in the diameters of the receiving pad 40 and the via hole 72 and is made depending on a combination thereof.

In FIG. 2D, there is carried out a desmear treatment for removing, through chemical hole cleaning, a smear in the via hole 72 which is generated by a laser processing.

In FIG. 2E, a seed layer 80 is formed on a surface of the first insulating layer 70 and an inside of the via hole 72 through a sputtering method or nonelectrolytic plating.

In FIG. 2F, a resin film constituted by a photosensitive resin or a liquid resist constituted by a photosensitive resin is arranged on a surface of the seed layer 80 to form a resist layer 90, and furthermore, the insulating layer 90 is subjected to patterning (exposure and development) to form an opening (a concave portion) 92 corresponding to a wiring pattern.

In FIG. 2G, Cu electrolytic plating is carried out over the opening 92 by feeding the seed layer 80 to form the receiving pad 50, and the via 30 and the wiring pattern are formed in the via hole 72.

In FIG. 2H, the resist layer 90 is stripped with a stripping solution and the seed layer 80 provided under the resist layer 90 is further removed through etching.

In FIG. 2I, a second insulating layer 98 is arranged on the surface of the first insulating layer 70. Then, the steps of FIGS. 2C to 2I are repeated so that a wiring board having a multilayer structure is obtained.

Thus, it is possible to manufacture a wiring board having a connecting structure of the via 30 and the receiving pads 40 and 50 shown in FIG. 1.
[Patent Document 1] JP-A-2003-218516
[Patent Document 2] JP-A-2003-008208

In the conventional manufacturing method, the step of opening the via hole 72 through the laser beam is carried out. For this reason, there is a problem in that a time required for the processing through a laser processing machine is correspondingly prolonged if the number of the vias is increased.

When the diameter of the via 30 is increasingly reduced, moreover, it is hard to remove a resin residue (a smear) on the bottom of the via which is generated after the laser processing (the desmear treatment shown in FIG. 2D). In the case in which the resin residue cannot be removed, there is a possibility that a connecting reliability of the via filling metal for forming the via 30 and the wiring pattern might be deteriorated.

When the desmear treatment using the resin etching is greatly carried out in order to remove the resin residue of the bottom of the via, moreover, a surface roughness of the resin forming the insulating layer is increased so that the via 30 is deformed or a wiring shape of the wiring pattern formed on the surface of the resin is nonuniform and a fine wiring is thus hard to form.

In order to eliminate the connecting failure of the via 30 and the wiring pattern which is caused by the variation in the irradiation of the laser beam, furthermore, the receiving pads 40 and 50 having larger diameters than the diameter of the via are formed on the upper and lower surfaces of the via 30 to provide the stopper for the laser beam. By the receiving pads 40 and 50, a position of each wiring of the wiring pattern is restricted. In the case in which a large number of wiring patterns are provided, a space for causing the wiring patterns to keep away from each other is to be provided.

In consideration of the circumstances, therefore, it is an object of the invention to provide a method of manufacturing a wiring board and the wiring board which solve the problems.

### SUMMARY OF THE INVENTION

In order to solve the problems, the invention has the following means.

According to a first aspect of the invention, there is provided a method of manufacturing a wiring board in which a via is formed on an insulating layer and a first wiring pattern to be connected to the via is formed on a surface of the insulating layer, comprising the steps of:

forming a wiring layer on a surface of a core substrate;

forming a seed layer on the surface of the core substrate and a surface of the wiring layer;

forming a resist layer on a surface of the seed layer and patterning the resist layer to form an opening for exposing a part of the wiring layer;

carrying out electrolytic plating over the opening by feeding the seed layer to form the via;

stripping the resist layer and removing the seed layer formed in a portion excluding the wiring layer;

arranging an insulating layer on a surface of the via and the surface of the wiring layer;

deleting a surface of the insulating layer to expose an end face of the via onto the insulating layer; and

forming, on the surface of the insulating layer, the first wiring pattern to be connected to an upper part of the via.

According to a second aspect of the invention, there is provided the method of manufacturing a wiring board according to the first aspect, wherein

the surface of the insulating layer is deleted through a blast processing or an etching treatment to expose an end face of the via onto the insulating layer.

According to a third aspect of the invention, there is provided the method of manufacturing a wiring board according to the first aspect, wherein

a connection is carried out by directly forming the first wiring pattern on the end face of the via.

According to a forth aspect of the invention, there is provided the method of manufacturing a wiring board according to the third aspect of the invention, wherein

a width of the first wiring pattern to be connected onto the end face of the via is formed to be smaller than a diameter of the via.

According to a fifth aspect of the invention, there is provided a wiring board in which a via is formed on an insulating layer and a first wiring pattern to be connected to the via is formed on a surface of the insulating layer, wherein

the first wiring pattern is directly connected onto an end face of the via.

According to a sixth aspect of the invention, there is provided the wiring board according to the fifth aspect, wherein

a width of the first wiring pattern to be connected onto the end face of the via which is formed smaller than a diameter of the via.

According to a seventh aspect of the invention, there is provided the method of manufacturing a wiring board according to the first or fifth aspect, wherein

a second wiring pattern is provided, and

the first wiring pattern and the second wiring pattern are perpendicular to the via.

According to an eighth aspect of the invention, there is provided the method of manufacturing a wiring board according to the first or fifth aspect, wherein

a via structure has a stack configuration.

According to the invention, the wiring layer and the seed layer are formed on the surface of the core substrate, the resist layer is formed on the surface of the seed layer, the resist layer is patterned to form the opening for exposing a part of the wiring layer, and the electrolytic plating is carried out over the opening by feeding the seed layer to form the via. Therefore, it is not necessary to carry out an opening step through a laser beam so that a desmear treatment after a laser processing is not required. Therefore, it is possible to correspondingly shorten a time required for the processing, thereby enhancing a production efficiency more greatly. In the case in which the diameter of the via is reduced, moreover, it is also possible to eliminate a contact failure of the via and the wiring pattern which is caused by an insufficient execution of a residue treatment. Therefore, it is also possible to reduce the diameter of the via.

### BRIEF DESCRIPTION OF THE DRAWINGS

FIG. 1A is a perspective view showing an example of structures of a via and a wiring pattern according to the conventional art,

FIG. 1B is a plan view showing the example of the structures of the via and the wiring pattern,

FIG. 2A is a view for explaining a method (No. 1) of manufacturing a wiring board according to the conventional art,

FIG. 2B is a view for explaining a method (No. 2) of manufacturing a wiring board according to the conventional art,

FIG. 2C is a view for explaining a method (No. 3) of manufacturing a wiring board according to the conventional art,

FIG. 2D is a view for explaining a method (No. 4) of manufacturing a wiring board according to the conventional art,

FIG. 2E is a view for explaining a method (No. 5) of manufacturing a wiring board according to the conventional art,

FIG. 2F is a view for explaining a method (No. 6) of manufacturing a wiring board according to the conventional art,

FIG. 2G is a view for explaining a method (No. 7) of manufacturing a wiring board according to the conventional art,

FIG. 2H is a view for explaining a method (No. 8) of manufacturing a wiring board according to the conventional art,

FIG. 2I is a view for explaining a method (No. 9) of manufacturing a wiring board according to the conventional art,

FIG. 3 is a longitudinal sectional view showing a first example of a wiring board according to the invention,

FIG. 4A is a perspective view showing a via structure applied to the first example of the wiring board according to the invention,

FIG. 4B is a plan view showing the via structure illustrated in FIG. 4A,

FIG. 5A is a perspective view showing an upper wiring pattern of the via structure according to the first example,

FIG. 5B is a plan view showing the via structure illustrated in FIG. 5A,

FIG. 6A is a view for explaining a method (No. 1) of manufacturing a wiring board according to the first example,

FIG. 6B is a view for explaining a method (No. 2) of manufacturing a wiring board according to the first example,

FIG. 6C is a view for explaining a method (No. 3) of manufacturing a wiring board according to the first example,

FIG. 6D is a view for explaining a method (No. 4) of manufacturing a wiring board according to the first example,

FIG. 6E is a view for explaining a method (No. 5) of manufacturing a wiring board according to the first example,

FIG. 6F is a view for explaining a method (No. 6) of manufacturing a wiring board according to the first example,

FIG. 6G is a view for explaining a method (No. 7) of manufacturing a wiring board according to the first example,

FIG. 6H is a view for explaining a method (No. 8) of manufacturing a wiring board according to the first example,

FIG. 6I is a view for explaining a method (No. 9) of manufacturing a wiring board according to the first example,

FIG. 6J is a view for explaining a method (No. 10) of manufacturing a wiring board according to the first example,

FIG. 6K is a view for explaining a method (No. 11) of manufacturing a wiring board according to the first example,

FIG. 7 is a perspective view showing a second example of the via structure applied to the wiring board according to the invention,

FIG. 8 is a perspective view showing a third example of the via structure applied to the wiring board according to the invention,

FIG. 9 is a perspective view showing a fourth example of the via structure applied to the wiring board according to the invention,

FIG. 10 is a perspective view showing a fifth example of the via structure applied to the wiring board according to the invention, and

FIG. 11 is a perspective view showing a sixth example of the via structure applied to the wiring board according to the invention.

### DETAILED DESCRIPTION OF THE PREFERRED EMBODIMENTS

The best mode for carrying out the invention will be described below with reference to the drawings.

### First Example

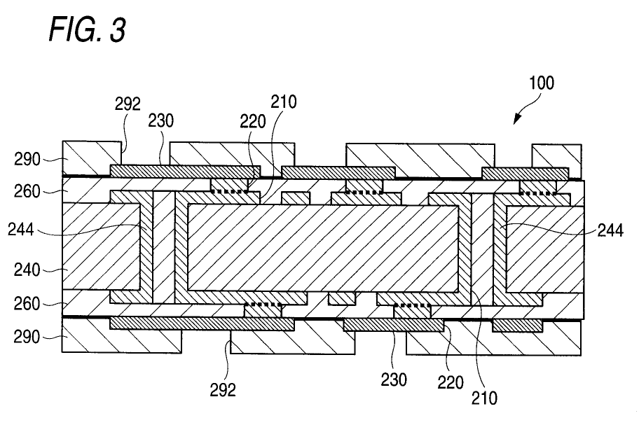

FIG. 3 is a longitudinal sectional view showing a first example of a wiring board according to the invention. FIG. 3 shows a state in a middle of a formation of a multilayer structure.

As shown in FIG. 3, a wiring board 100 has a multilayer structure in which insulating layers and wiring layers are arranged on upper and lower surfaces of a core substrate 240, and has a via structure 200 in which electrolytic Cu plating is carried out over a via forming opening provided by patterning a resist layer to form a via 220.

A through hole 244 and a wiring pattern 210 to be connected to the through hole 244 are formed on the core substrate 240. While the core substrate using the through hole 244 is employed in the example, the core substrate is not restricted if an insulating layer can be formed. The via 220 taking a cylindrical shape is mounted on an upper surface of the wiring pattern 210 and a wiring pattern 230 is formed on an upper surface of the via 220.

The via structure 200 includes the wiring pattern 210, the via 220 and the wiring pattern 230, and the through hole 244, the wiring pattern 210, the via 220 and the wiring pattern 230 are electrically connected respectively.

In the via structure 200, the via 220 is formed without using the laser processing. Therefore, a desmear treatment is not required after the laser processing. Consequently, it is possible to correspondingly shorten a time required for the processing, thereby enhancing a production efficiency more greatly. In the case in which a diameter of the via is reduced, moreover, it is possible to eliminate a contact failure of the via and the wiring pattern which is caused by an insufficient execution of a residue treatment. Therefore, the diameter of the via can also be reduced.

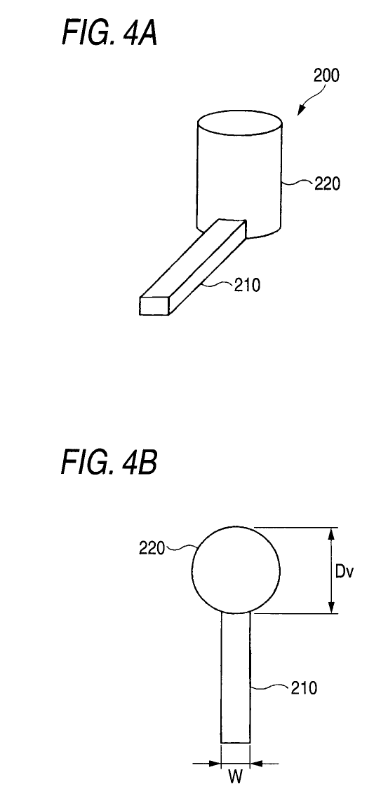

FIG. 4A is a perspective view showing a first example of a via structure applied to the wiring board according to the invention. FIG. 4B is a plan view showing the via structure illustrated in FIG. 4A. In FIGS. 4A and 4B, the insulating layer is not shown for easy understanding of the via structure.

As shown in FIGS. 4A and 4B, the via structure 200 has the lower wiring pattern 210 formed on a lower surface side of the insulating layer and the via 220 taking a cylindrical shape and mounted on the upper surface of the lower wiring pattern 210. A width W (for example, W=15 μm) of the lower wiring pattern 210 is set to be smaller than a diameter Dv (for example, Dv=60 μm) of the via 220 (W<Dv). Moreover, the upper surface of the lower wiring pattern 210 is directly connected to a lower end face of the via 220.

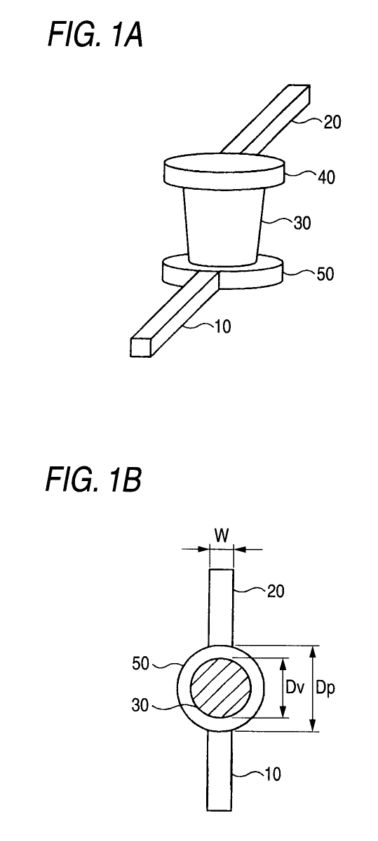

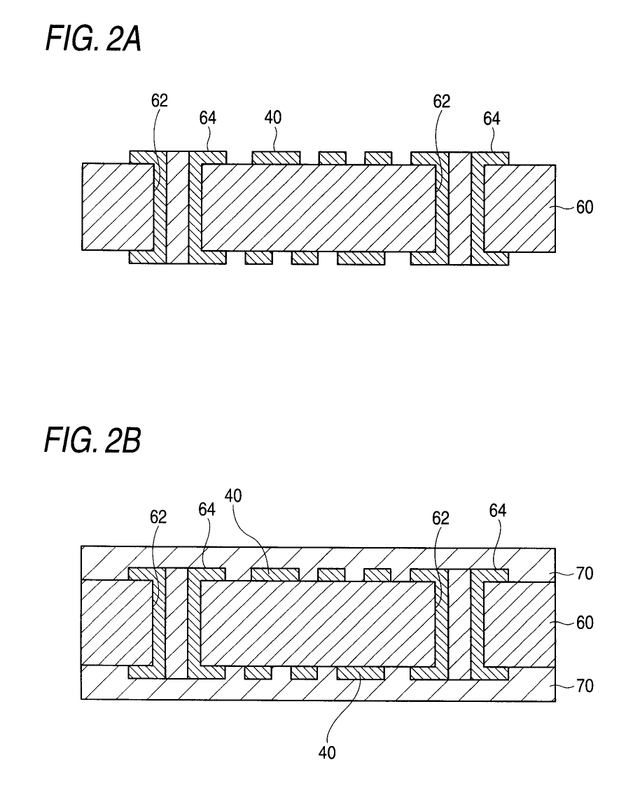

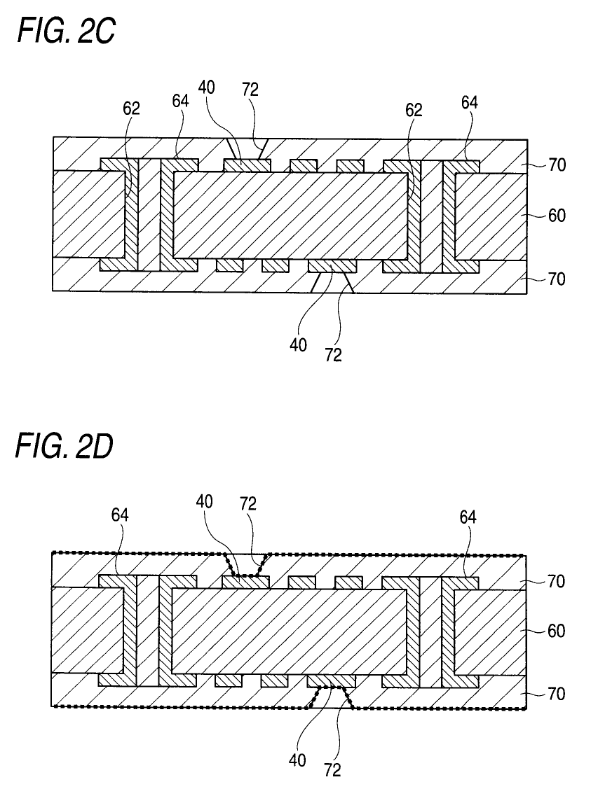

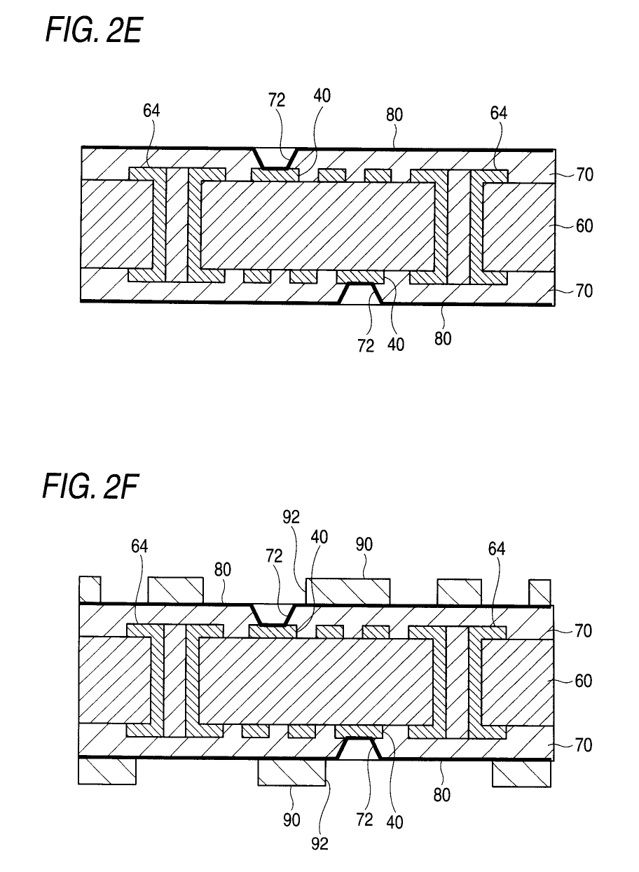

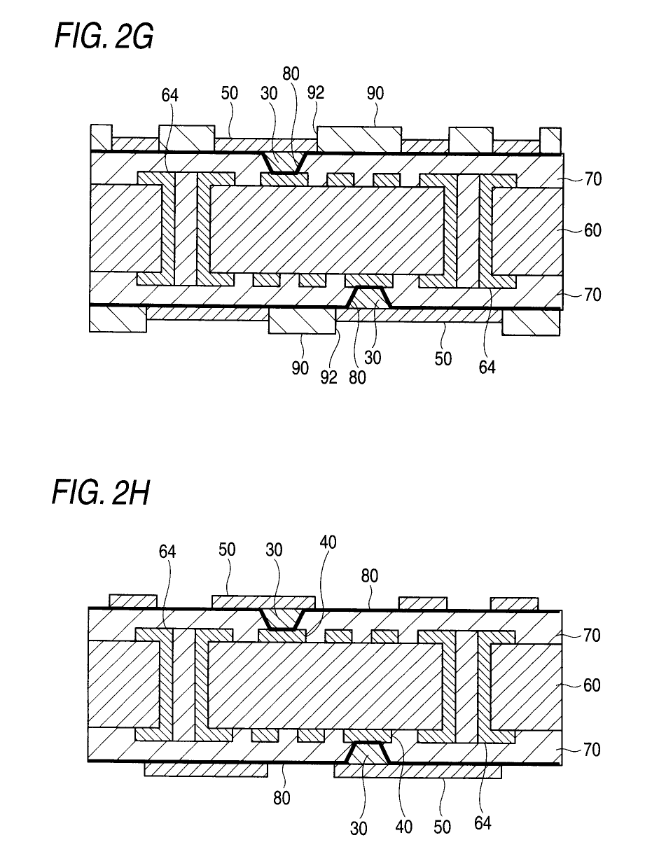

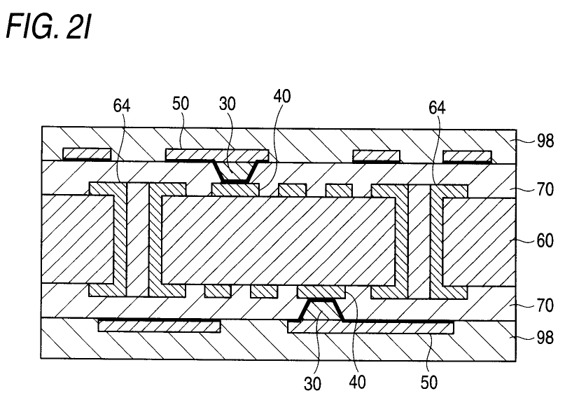

The lower end face of the via 220 is not provided with a receiving pad to be used in an irradiation of a laser beam (the conventional structure shown in FIG. 1A). Therefore, the other wiring patterns are disposed so as not to come in contact with an outer periphery of the via 220. However, they do not need to be turned greatly differently from the conventional art. Consequently, it is possible to decrease restrictions when setting a wiring path for the wiring pattern.

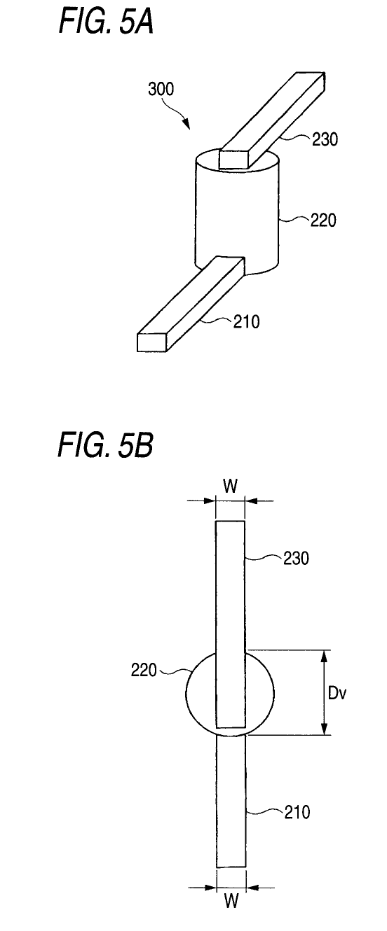

As shown in FIGS. 5A and 5B, in the via structure 300, the upper wiring pattern 230 is formed to be directly connected to an upper end face of the via 220. A width W (for example, W=15 μm) of the upper wiring pattern 230 is set to be smaller than the diameter Dv (for example, Dv=60 μm) of the via 220 (W<Dv). The upper end face of the via 220 is not provided with a receiving pad for maintaining a connection to the upper wiring pattern 230 (the conventional structure shown in FIG. 1A). When the other wiring patterns are to be disposed so as not to come in contact with an outer periphery of the via 220, therefore, they do not need to be turned greatly. Consequently, it is possible to decrease restrictions when setting the wiring path for the wiring pattern.

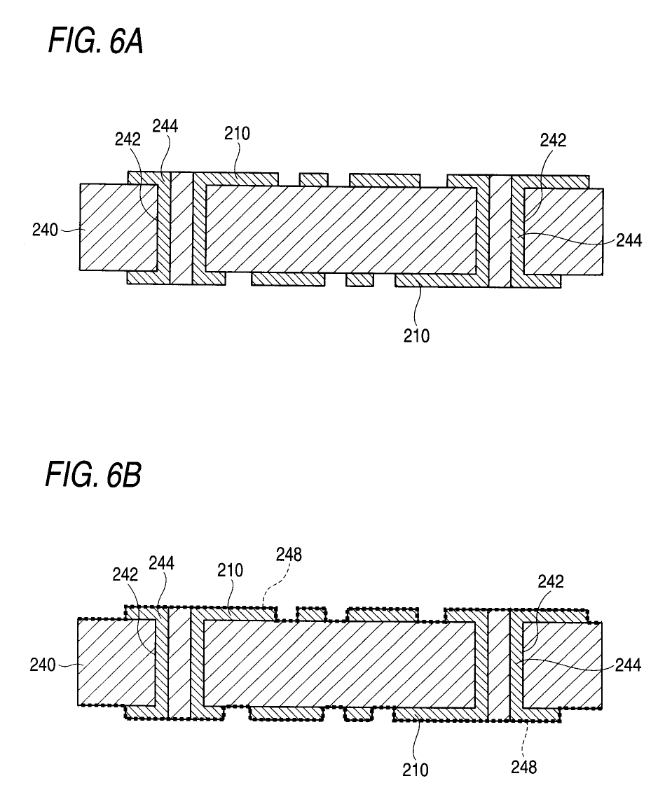

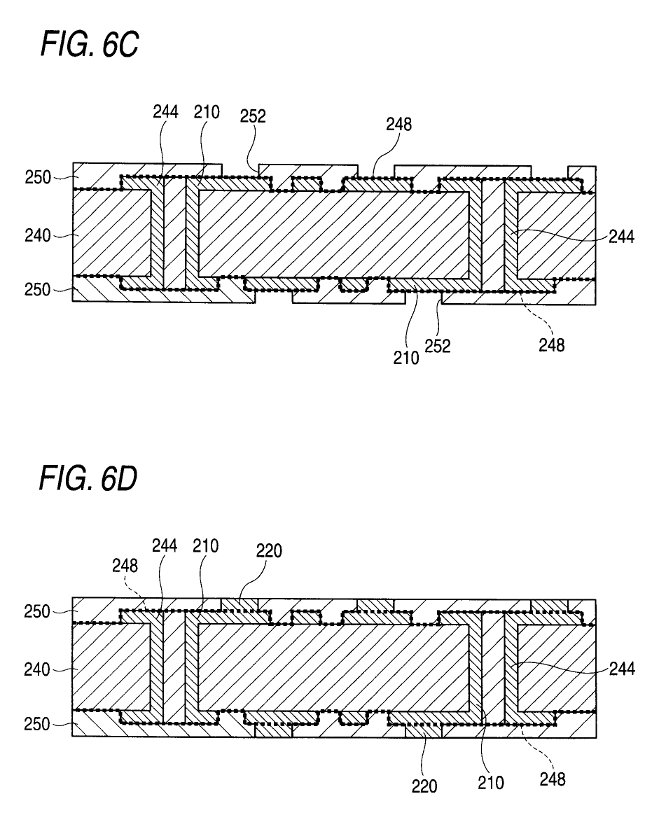

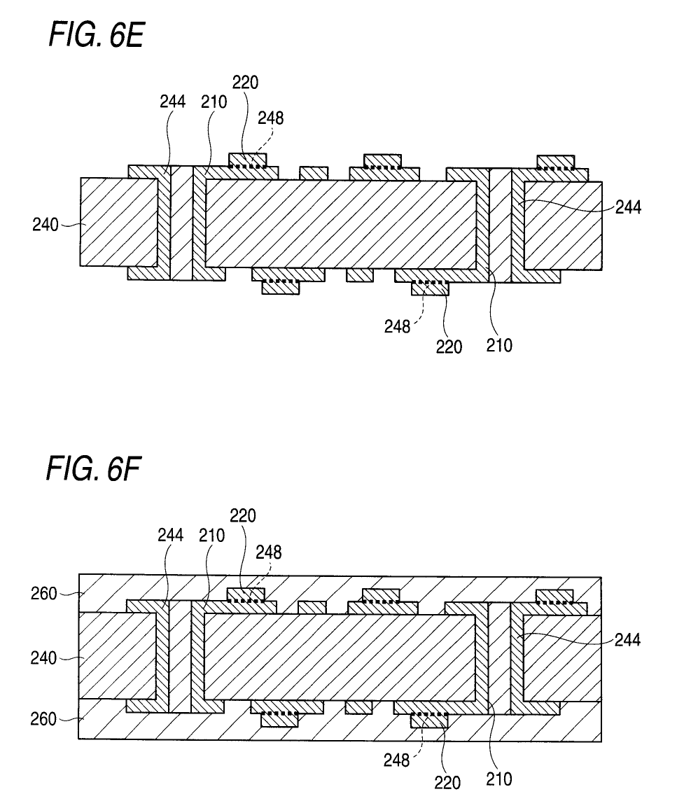

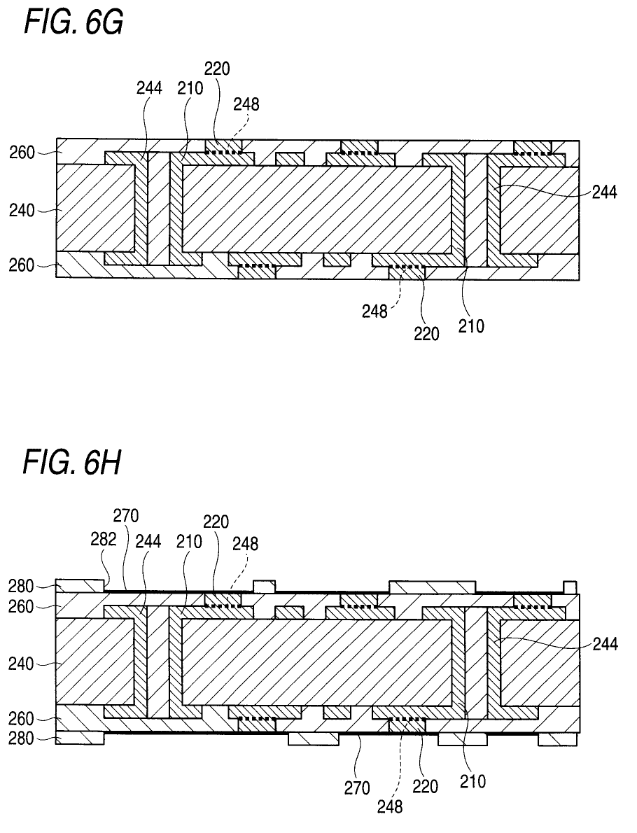

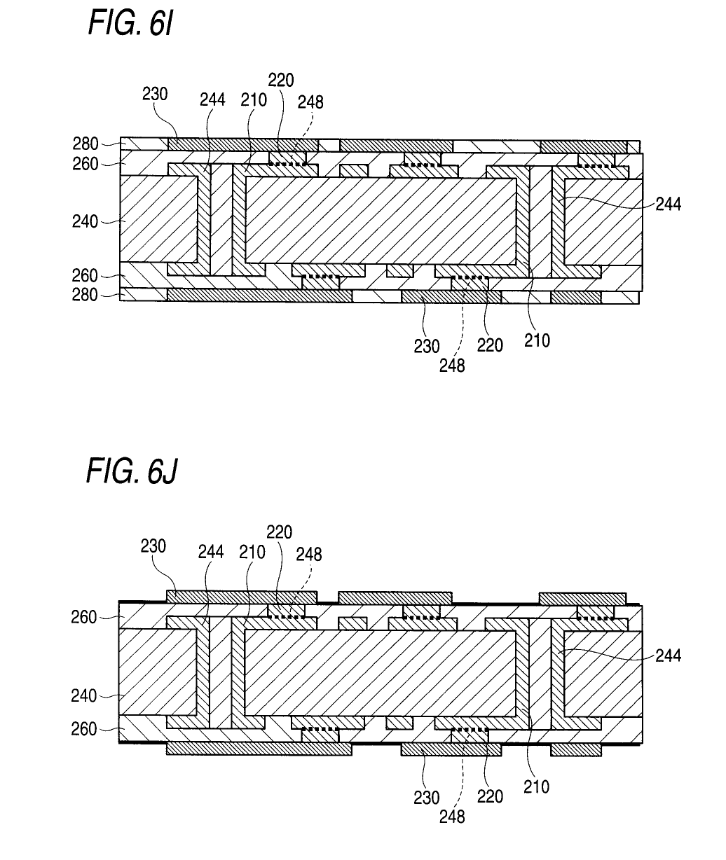

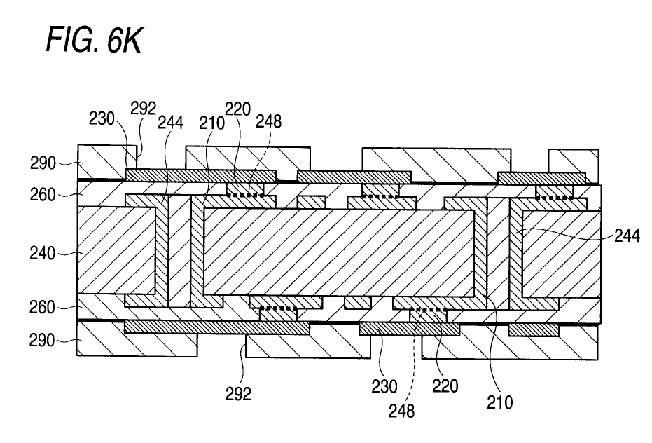

A method of manufacturing a wiring board having the via structure will be described below with reference to FIGS. 6A (No. 1) to FIG. 6K (No. 11). In the example, description will be given by taking, as an example, a wiring board having a multilayer structure in which insulating layers and wiring layers are arranged on both upper and lower surfaces of a substrate.

In FIG. 6A, a hole 242 penetrating in a vertical direction is formed on the core substrate 240, and the plated through hole 244 and the wiring pattern 210 connected to the plated through hole 244 are formed in the hole 242.

In FIG. 6B, a first seed layer 248 (shown in a broken line) is formed on both sides of the core substrate 240 by using a sputtering method or a nonelectrolytic plating method.

In FIG. 6C, a resist layer 250 is formed on both sides of the core substrate 240. The resist layer 250 is formed by a method of laminating a resin film constituted by a photosensitive resist or a method of applying a liquid resist constituted by a photosensitive resist.

Subsequently, exposure using ultraviolet rays and development are carried out over the resist layer 250 to form a via forming opening 252. The via forming opening 252 serves to form the via 220 and a method of forming the via 220 by irradiating a laser beam as in the conventional art is not used. Even if the via 220 is formed in a slightly shifted position from the wiring pattern 210, therefore, an electrical conduction can be carried out if the via 220 is formed in such a manner that a part of the wiring pattern 210 is exposed. Therefore, it is not necessary to provide a receiving pad having a larger diameter than the diameter of the via 220 below the via 220. Moreover, restrictions are also prevented from being caused by plating for providing the receiving pad.

Even if the width W of the wiring pattern 210 is smaller or larger than the diameter Dv of the via 220, furthermore, it is possible to carry out an electrical connection of the wiring pattern 210 to the via 220. Also in the case in which an error is made due to a variation in the position of the wiring pattern 210, a variation in the width of the wiring pattern 210, a variation in the position of the via 220 or a variation in the diameter of the via 220, therefore, the electrical connection can be carried out if the wiring pattern 210 and the via 220 are partially connected to each other.

In FIG. 6D, electrolytic Cu plating is carried out by feeding the first seed layer 248 to deposit Cu on the via forming opening 252 so that the via 220 is formed. Thus, an opening step to be carried out through a laser beam is not required so that a desmear treatment is not required after a laser processing. Consequently, it is possible to correspondingly shorten a time required for the processing, thereby enhancing a production efficiency more greatly. In the case in which the diameter of the via is reduced, moreover, it is also possible to eliminate a contact failure of the via and the wiring pattern which is caused by an insufficient execution of a residue treatment. Therefore, the diameter of the via can also be reduced.

In FIG. 6E, the resist layer 250 is stripped with a stripping solution. Subsequently, the first seed layer 248 formed on portions other than the via 220 is removed by etching.

In FIG. 6F, a resin layer formed by an epoxy resin is arranged on both sides of the core substrate 240 to form a first insulating layer 260. The first insulating layer 260 is formed by a method of laminating a resin film such as an epoxy resin or a method of applying a liquid resist.

In FIG. 6G, a surface of the first insulating layer 260 is removed in a uniform thickness through a blasting treatment or an etching treatment. The blasting treatment or the etching treatment is carried out until the surface of the via 220 is exposed.

In FIG. 6H, a second seed layer 270 is formed on the surface of the first insulating layer 260 by using a sputtering method or a nonelectrolytic plating method. Subsequently, a resist layer 280 is formed on a surface of the second seed layer 270. The resist layer 280 is formed by a method of laminating a resin film constituted by a photosensitive resist or a method of applying a liquid resist constituted by a photosensitive resist.

Next, the resist layer 280 is subjected to exposure using ultraviolet rays and development so that a wiring pattern forming opening 282 is formed. The wiring pattern forming opening 282 serves to form the wiring pattern 230 (see FIG. 5A)

Even if the width W of the wiring pattern 230 is smaller or larger than the diameter Dv of the via 220, furthermore, it is possible to carry out an electrical connection of the wiring pattern 230 to the via 220. Also in the case in which an error is made due to a variation in the position of the wiring pattern 230, a variation in the width of the wiring pattern 230, a variation in the position of the via 220 or a variation in the diameter of the via 220, therefore, the electrical connection can be carried out if the wiring pattern 230 and the via 220 are partially connected to each other.

In FIG. 6I, the electrolytic Cu plating is carried out by feeding the second seed layer 270 to deposit Cu on the wiring pattern forming opening 282 so that the wiring pattern 230 is formed. In FIG. 6I and succeeding drawings, the Cu is deposited and integrated with the second seed layer 270 formed in a bottom part of the wiring pattern forming opening 282. For this reason, the second seed layer 270 is not shown.

In FIG. 6J, the resist layer 280 is stripped with a stripping solution.

In FIG. 6K, a resist layer 290 is formed on surfaces of the wiring pattern 280 and the first insulating layer 260. The resist layer 290 is formed by a method of laminating a resin film constituted by a photosensitive resist or a method of applying a liquid resist constituted by a photosensitive resist.

Subsequently, the resist layer 290 is subjected to exposure using ultraviolet rays and development to form a via forming opening 292. Then, the steps of FIGS. 6D to 6K are repeated so that there is obtained a multilayer wiring board having the via structure 200 in which an insulating layer is provided.

In FIG. 6K, the second seed layer 270 is left on a lower side of the resist layer 290. When the steps of FIGS. 6D to 6K are to be repeated, a power is fed to the second seed layer 270 to carry out the electrolytic Cu plating so that the via 220 to be connected to an upper surface of the wiring pattern 230 is formed. In FIG. 6E to be then carried out, the resist layer 290 is stripped with a stripping solution and the second seed layer 270 formed in portions other than the via 220 is thereafter removed by etching.

Although the description has been given by taking, as an example, a build-up wiring board in which insulating layers and wiring layers are provided on both upper and lower surfaces of the core substrate 240 in the first example, this is not restricted but it is also possible to employ a structure in which they are provided on either of the upper and lower surfaces of the core substrate 240.

While the wiring board 100 is shown as an example in the first example, moreover, this is not restricted but the invention may be applied to a wiring board having another structure or a wiring board on which a semiconductor chip or a photoelectric converting device is mounted if the via structure 200 is employed in the configuration in which the insulating layers and the wiring layers are provided.

### Second Example

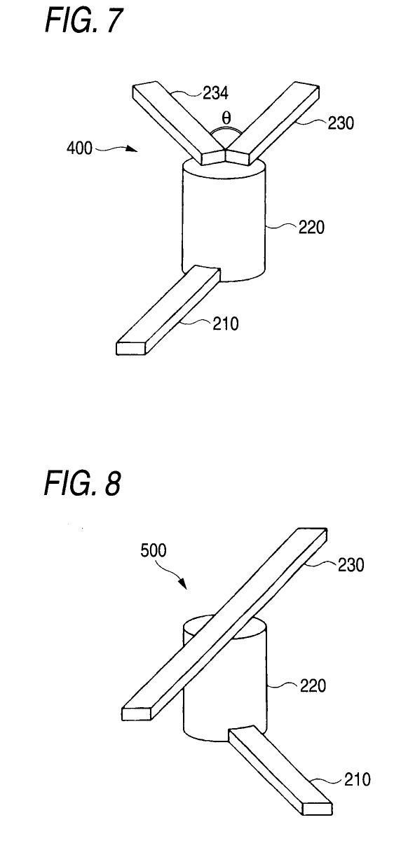

FIG. 7 is a perspective view showing a second example of the via structure applied to the wiring board according to the invention. In FIG. 7, the same portions as those in each of the examples have the same reference numerals and description thereof will be omitted. In FIG. 7, moreover, an insulating layer is not shown for easy understanding of the via structure.

As shown in FIG. 7, a via structure 400 has a lower wiring pattern 210 formed on a lower surface side of the insulating layer, a cylindrical via 220 mounted on an upper surface of the lower wiring pattern 210, and upper wiring patterns 230 and 234 connected to an upper end face of the via 220. A width W of each of the lower wiring pattern 210 and the upper wiring patterns 230 and 234 (for example, W=15 μm) is set to be smaller than a diameter Dv of the via 220 (for example, Dv=60 μm) (W<Dv).

The upper wiring patterns 230 and 234 are formed to be extended in different directions (an angle of θ) from the upper end face of the via 220 and are disposed like a V shape as seen from above. Thus, the wiring patterns 230 and 234 can also be provided on the upper end face of the via 220.

Also in the second example, moreover, a receiving pad (the conventional structure shown in FIG. 1A) in an irradiation of a laser beam is not provided on upper and lower surfaces of the via 220. Therefore, the disposition is carried out without a contact with the other wiring patterns and a great turn in the conventional art does not need to be made.

Since a method of manufacturing a wiring board having the via structure 400 according to the second example is the same as that in FIGS. 6A to 6K according to the first example, description thereof will be omitted.

### Third Example

FIG. 8 is a perspective view showing a third example of the via structure applied to the wiring board according to the invention. In FIG. 8, the same portions as those in each of the examples have the same reference numerals and description thereof will be omitted. In FIG. 8, moreover, an insulating layer is omitted for easy understanding of the via structure.

As shown in FIG. 8, a via structure 500 has a lower wiring pattern 210 formed on a lower surface side of the insulating layer, a cylindrical via 220 mounted on an upper surface of the lower wiring pattern 210, and an upper wiring pattern 230 connected to an upper end face of the via 220. A width W of each of the lower wiring pattern 210 and the upper wiring pattern 230 (for example, W=15 μm) is set to be smaller than a diameter Dv of the via 220 (for example, Dv=60 μm) (W<Dv).

The upper wiring pattern 230 is formed to be extended in a direction of 180 degrees from the upper end face of the via 220 and is disposed straight as seen from above. Thus, the wiring pattern 230 can also be provided on the upper end face of the via 220.

Also in the third example, moreover, a receiving pad (the conventional structure shown in FIG. 1A) in an irradiation of a laser beam is not provided on upper and lower surfaces of the via 220. Therefore, the disposition is carried out without a contact with the other wiring patterns and a great turn in the conventional art does not need to be made.

Since a method of manufacturing a wiring board having the via structure 500 according to the third example is the same as that in FIGS. 6A to 6K according to the first example, description thereof will be omitted.

### Fourth Example

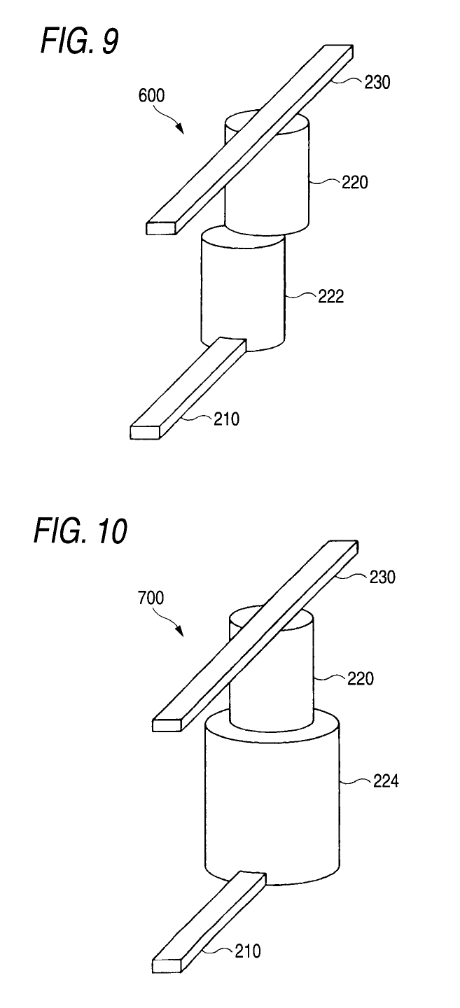

FIG. 9 is a perspective view showing a fourth example of the via structure applied to the wiring board according to the invention. In FIG. 9, the same portions as those in each of the examples have the same reference numerals and description thereof will be omitted. In FIG. 9, moreover, an insulating layer is omitted for easy understanding of the via structure.

As shown in FIG. 9, a via structure 600 has a stack configuration in which cylindrical vias 220 and 222 are stacked between a lower wiring pattern 210 and an upper wiring pattern 230.

The via 220 in an upper stage and the via 222 in a lower stage have almost equal outside diameters and they can be stacked through two continuous executions of the via forming steps in FIGS. 6C to 6H according to the first example.

Also in the case in which the via stack configuration is employed as in the example, a receiving pad (the conventional structure shown in FIG. 1A) in an irradiation of a laser beam is not provided between the vias 220 and 222. Even if the vias 220 and 222 are slightly shifted relatively in a radial direction (a circumferential direction), therefore, an electrical connection can be carried out if the vias 220 and 222 are partially connected to each other.

Since a method of manufacturing a wiring board having the via structure 600 according to the fourth example is the same as that in FIGS. 6A to 6K according to the first example, description thereof will be omitted. Moreover, the method is different from that in the first example in that the via stack configuration is obtained by two repetitions of the via forming steps in FIGS. 6C to 6H.

### Fifth Example

FIG. 10 is a perspective view showing a fifth example of the via structure applied to the wiring board according to the invention. In FIG. 10, the same portions as those in each of the examples have the same reference numerals and description thereof will be omitted. In FIG. 10, moreover, an insulating layer is omitted for easy understanding of the via structure.

As shown in FIG. 10, a via structure 700 has a stack configuration in which cylindrical vias 220 and 224 are stacked between a lower wiring pattern 210 and an upper wiring pattern 230.

The via 224 in a lower stage has a larger outside diameter than the via 220 in an upper stage, and stacking can be carried out through two continuous executions of the via forming step shown in FIGS. 6C to 6H according to the first example.

In the via structure 700 according to the example, the outside diameter of the via 224 is larger than that of the via 220. Even if the vias 220 and 224 are slightly shifted relatively in a radial direction (a circumferential direction), therefore, it is possible to carry out an electrical connection of the vias 220 and 224.

Since a method of manufacturing a wiring board having the via structure 700 according to the fifth example is the same as that in FIGS. 6A to 6K according to the first example, description thereof will be omitted. Moreover, the method is different from that in the first example in that the via stack configuration is obtained by two repetitions of the via forming steps in FIGS. 6C to 6H.

### Sixth Example

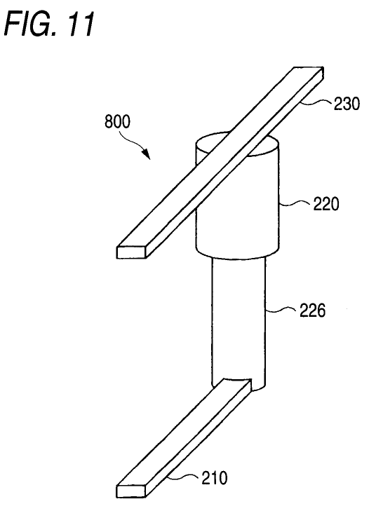

FIG. 11 is a perspective view showing a sixth example of the via structure applied to the wiring board according to the invention. In FIG. 11, the same portions as those in each of the examples have the same reference numerals and description thereof will be omitted. In FIG. 11, moreover, an insulating layer is omitted for easy understanding of the via structure.

As shown in FIG. 11, a via structure 800 has a stack configuration in which cylindrical vias 220 and 226 are stacked between a lower wiring pattern 210 and an upper wiring pattern 230.

The via 226 in a lower stage has a smaller outside diameter than the via 220 in an upper stage, and stacking can be carried out through two continuous executions of the via forming step shown in FIGS. 6C to 6H according to the first example.

In the via structure 800 according to the example, the outside diameter of the via 226 is larger than that of the via 220. Even if the via 220 and a via 224 are slightly shifted relatively in a radial direction (a circumferential direction), therefore, it is possible to carry out an electrical connection of the vias 220 and 224.

Since a method of manufacturing a wiring board having the via structure 800 according to the sixth example is the same as that in FIGS. 6A to 6K according to the first example, description thereof will be omitted. Moreover, the method is different from that in the first example in that the via stack configuration is obtained by two repetitions of the via forming steps in FIGS. 6C to 6H.

What is claimed is:

1. A method of manufacturing a wiring board in which a via is formed on an insulating layer and a first wiring pattern to be connected to the via is formed on a surface of the insulating layer, comprising the steps of:
forming a wiring layer on a surface of a core substrate;
forming a seed layer on the surface of the core substrate and a surface of the wiring layer;
forming a resist layer on a surface of the seed layer and patterning the resist layer to form an opening for exposing a part of the wiring layer;
carrying out electrolytic plating over the opening by feeding the seed layer to form the via;
stripping the resist layer and removing the seed layer formed in a portion excluding the wiring layer;
arranging an insulating layer on a surface of the via and the surface of the wiring layer;
deleting a surface of the insulating layer to expose an end face of the via onto the insulating layer; and
forming, on the surface of the insulating layer, the first wiring pattern to be connected to an upper part of the via.

2. The method of manufacturing a wiring board according to claim 1, wherein
the surface of the insulating layer is deleted through a blast processing or an etching treatment to expose an end face of the via onto the insulating layer.

3. The method of manufacturing a wiring board according to claim 1, wherein
a connection is carried out by directly forming the first wiring pattern on the end face of the via.

4. The method of manufacturing a wiring board according to claim 3, wherein
a width of the first wiring pattern to be connected onto the end face of the via is formed to be smaller than a diameter of the via.

5. A wiring board in which a via is formed on an insulating layer and a first wiring pattern to be connected to the via is formed on a surface of the insulating layer, wherein
the first wiring pattern is directly connected onto an end face of the via.

6. The wiring board according to claim 5, wherein
a width of the first wiring pattern to be connected onto the end face of the via is formed to be smaller than a diameter of the via.

7. The method of manufacturing a wiring board according to claim 1, wherein
a second wiring pattern is provided, and
the first wiring pattern and the second wiring pattern are perpendicular to the via.

8. The method of manufacturing a wiring board according to claim 5, wherein
a second wiring pattern is provided, and
the first wiring pattern and the second wiring pattern are perpendicular to the via.

9. The method of manufacturing a wiring board according to claim 1, wherein
a via structure has a stack configuration.

10. The method of manufacturing a wiring board according to claim 5, wherein
a via structure has a stack configuration.
